(19) United States
(12) Patent Application Publication
(10) Pub. No.: US 2016/0084938 A1
(43) Pub. Date: Mar. 24, 2016

(54) SIGNAL DETECTION APPARATUS, SERVER APPARATUS AND LOCATION ESTIMATION SYSTEM

(71) Applicant: KABUSHIKI KAISHA TOSHIBA, Tokyo (JP)

(72) Inventors: Yusuke DOI, Yokohama (JP); Yuji TOHZAKA, Kawasaki (JP); Takafumi SAKAMOTO, Tokyo (JP); Yumiko SAKAI, Fujisawa (JP); Toshio ITO, Kawasaki (JP); Toru TANIGUCHI, Yokohama (JP); Tatsuma ISHIHARA, Kawasaki (JP)

(21) Appl. No.: 14/848,644

(22) Filed: Sep. 9, 2015

(30) Foreign Application Priority Data
Sep. 19, 2014 (JP) 2014-191883

(51) Int. Cl. G01S 5/20; H04W 4/02; H04W 56/00; H05K 7/14; H04W 72/10

(52) U.S. Cl. CPC G01S 5/20; H05K 7/1485; H04W 72/10; H04W 56/001; H04W 4/023; H04W 84/18

(57) ABSTRACT

According to an embodiment, a signal detection apparatus includes an allocator, a generator and a limiter. The allocator allocates priority levels to signal characteristics of the signal block. The generator generates feature information representing a feature of a time domain of the signal block for each of signal characteristics. The limiter, if a total information volume of the pieces of feature information exceeds an upper limit information volume corresponding to the bandwidth, selects some of the pieces of feature information based on the priority levels allocated to the pieces of feature information to limit an information volume of the selected pieces of feature information not to exceed the upper limit information volume.

### CROSS-REFERENCE TO RELATED APPLICATIONS

This application is based upon and claims the benefit of priority from Japanese Patent Application No. 2014-191883, filed Sep. 19, 2014, the entire contents of which are incorporated herein by reference.

### FIELD

Embodiments described herein relate generally to estimation of the location of a signal source.

### BACKGROUND

There is conventionally proposed a technique of estimating the location of a sound source using a microphone array. To estimate the location of a sound source in a wide space with high accuracy, however, it is necessary to increase the aperture length of the microphone array.

If the pieces of information of sounds received by a plurality of microphones distributed and arranged in a wide area are collected via wired communication, the cost of wiring is high and the arrangement of the plurality of microphones is also limited. On the other hand, collecting such information via wireless communication is preferable in terms of the cost and the degree of freedom of the arrangement of the microphones since no wiring is required. However, the usable bandwidth of wireless communication is typically limited, as compared with wired communication. Therefore, if a number of microphones are arranged, the volume of collected information readily reaches the upper limit of the usable bandwidth. If the volume of the pieces of information collected from the microphones is simply reduced, information having an influence on the accuracy of location estimation may deteriorate or may be lost. Consequently, it is not easy to estimate the location of a sound source or another signal source in a wide space with high accuracy.

### BRIEF DESCRIPTION OF THE DRAWINGS

FIG. 1 is a block diagram exemplifying a location estimation system according to the first embodiment;

FIG. 2 is a block diagram exemplifying a signal detection apparatus according to the first embodiment;

FIG. 3 is a block diagram exemplifying a server apparatus according to the first embodiment;

FIG. 4 is a view for explaining coarse-grained estimation processing executed by a coarse-grained estimator shown in FIG. 3; and

FIG. 5 is a timing chart for explaining fine-grained estimation processing executed by a fine-grained estimator shown in FIG. 3.

### DETAILED DESCRIPTION

Embodiments will be described below with reference to the accompanying drawings.

According to an embodiment, a signal detection apparatus includes a sensor, a clock, a first generator, an allocator, a second generator, a receiver, a limiter and a transmitter. The sensor detects a signal. The clock is synchronized with another clock incorporated in another signal detection apparatus. The first generator generates first feature information representing a feature of a frequency domain of a signal block obtained by performing block formation of the signals from the sensor at every predetermined time based on time information of the clock. The allocator allocates priority levels to a plurality of signal characteristics of the signal block. The second generator generates second feature information representing a feature of a time domain of the signal block for each of the plurality of signal characteristics. The receiver receives a server command indicating a bandwidth allocated by a server apparatus from the server apparatus. The limiter, if a total information volume of the pieces of second feature information exceeds an upper limit information volume corresponding to the bandwidth, selects some of the pieces of second feature information and discards remaining pieces of second feature information based on the priority levels allocated to the pieces of second feature information to limit an information volume of the selected pieces of second feature information not to exceed the upper limit information volume. The transmitter transmits the first feature information and the selected pieces of second feature information to the server apparatus.

According to another embodiment, a server apparatus includes a receiver, an apparatus manager, a feature information manager, a first estimator, a second estimator, a determiner, a bandwidth allocation manager, a generator, and a transmitter. The receiver receives, from each of a plurality of signal detection apparatuses, first feature information representing a feature of a frequency domain of a signal detected by the signal detection apparatus, and second feature information representing a feature of a time domain of the signal. The apparatus manager manages pieces of location information of the plurality of signal detection apparatuses. The feature information manager maps the first feature information and the second feature information to the location information of the corresponding signal detection apparatus. The first estimator obtains a coarse-grained estimation result by estimating, based on the mapped first feature information, in which of a plurality of regions determined based on the location information of the signal detection apparatus each of at least one signal source is located, and a characteristic of a signal transmitted by the signal source. The second estimator estimates, based on the coarse-grained estimation result and the mapped second feature information, a location of each of the at least one signal source with a finer granularity than that of the first estimator. The determiner specifies missing feature information indicating second feature information which needs to be collected, by determining for each of the at least one signal source whether second feature information corresponding to the characteristic of the signal transmitted by the signal source has been sufficiently collected. The bandwidth allocation manager controls bandwidth allocation to the plurality of signal detection apparatuses based on the missing feature information and a bandwidth usable by the plurality of signal detection apparatuses to transmit the first feature information and the second feature information, and obtains bandwidth allocation information indicating a bandwidth allocated to each of the plurality of signal detection apparatuses. The generator generates a server command for each of the plurality of signal detection apparatuses based on the missing feature information and the bandwidth allocation information. The transmitter transmits the server command to the plurality of signal detection apparatuses.

According to another embodiment, a location estimation system includes the server apparatus and the signal detection apparatuses described above.

Note that the same or similar reference numerals denote the same or similar elements hereinafter and a repetitive description thereof will be basically omitted. When, for example, a plurality of identical or similar elements exist, a common reference numeral may be used to explain the respective elements without discriminating between them or a branch number may be used in addition to the common reference numeral to discriminate and explain each element.

### First Embodiment

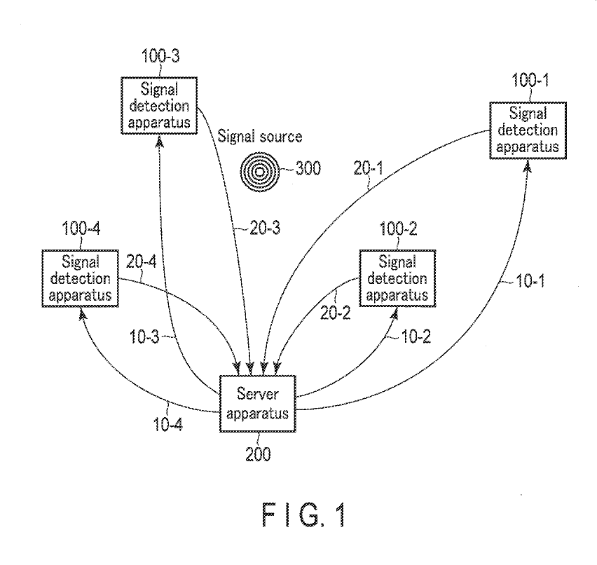

As exemplified in FIG. 1, a location estimation system according to the first embodiment includes signal detection apparatuses 100-1, 100-2, 100-3, and 100-4, and a server apparatus 200. Note that the total number of signal detection apparatuses 100 may be five or more, and the total number of server apparatuses 200 may be two or more.

The server apparatus 200 controls the signal detection apparatuses 100-1, 100-2, 100-3, and 100-4 via server commands 10-1, 10-2, 10-3, and 10-4, respectively, and collects pieces of feature information 20-1, 20-2, 20-3, and 20-4 from the signal detection apparatuses 100-1, 100-2, 100-3, and 100-4, respectively. Each piece of feature information 20 is information representing the feature of a signal detected by a corresponding one of the signal detection apparatuses 100.

Based on the collected pieces of feature information 20, the server apparatus 200 estimates the location of a signal source 300 existing in a space. Furthermore, if feature information necessary to estimate the location of the signal source 300 is missing, the server apparatus 200 may cause the signal detection apparatus 100 to transmit the feature information. Note that the server apparatus 200 controls a bandwidth allocated to each signal detection apparatus 100 so that the bandwidth is not saturated by transmitting the feature information 20. On the other hand, the signal detection apparatus 100 transmits feature information having a high priority level to the server apparatus 200 according to the bandwidth allocated by the server apparatus 200.

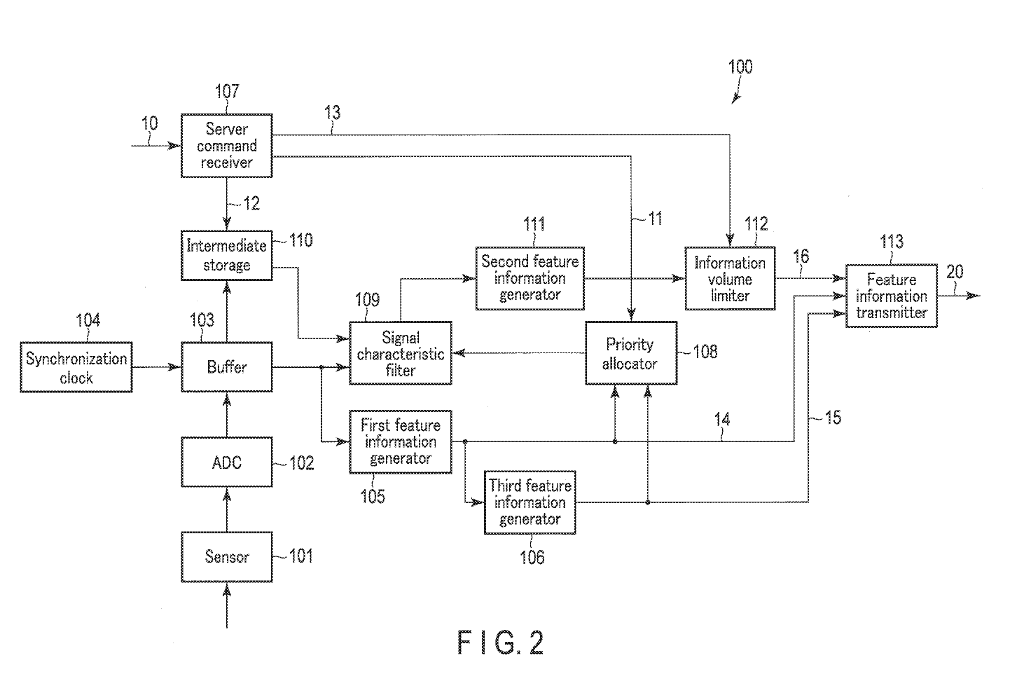

As exemplified in FIG. 2, the signal detection apparatus 100 according to the first embodiment includes a sensor 101, an ADC (Analog-to-Digital Converter) 102, a buffer 103, a synchronization clock 104, a first feature information generator 105, a third feature information generator 106, a server command receiver 107, a priority allocator 108, a signal characteristic filter 109, an intermediate storage 110, a second feature information generator 111, an information volume limiter 112, and a feature information transmitter 113.

The sensor 101 detects a signal transmitted by the signal source 300 or another signal source. This signal may be, for example, a physical vibration such as an acoustic wave or another wave. The sensor 101 can be implemented by, for example, a microphone. The sensor 101 converts the detected signal into an electric signal, and outputs the electric signal to the ADC 102.

The ADC 102 receives the electric signal from the sensor 101, and converts it into a digital signal. This digital signal represents the waveform of the detected signal. The ADC 102 outputs the digital signal to the buffer 103.

The digital signal from the ADC 102 is written in the buffer 103. An operation of writing the digital signal in the buffer 103 is performed according to time information managed by the synchronization clock 104. As will be described later, the time information of the synchronization clock 104 is in synchronism with that of a synchronization clock 104 incorporated in another signal detection apparatus 100. Therefore, a detected signal associated with given time information in a given signal detection apparatus 100 can be considered to have been detected simultaneously with a detected signal associated with the same time information in another signal detection apparatus 100.

Digital signals written in the buffer 103 are collectively read out at every predetermined time based on the time information of the synchronization clock 104. The digital signals having undergone block formation at every predetermined time will be referred to as a signal block hereinafter. The signal block is output to the first feature information generator 105, signal characteristic filter 109, and intermediate storage 110.

The synchronization clock 104 functions as the clock of the signal detection apparatus 100, and provides time information to the buffer 103. For example, the synchronization clock 104 may obtain time information (timer value) by performing a count-up operation in accordance with a clock signal. The synchronization clock 104 is controlled to be synchronized with the synchronization clock 104 incorporated in the other signal detection apparatus 100. For example, if the signal detection apparatus 100 corresponds to a wireless LAN apparatus complying with IEEE802.11, the synchronization clock 104 may be implemented by a TSF (Timing Synchronization Function) timer. Although the synchronization processing of TSF timers changes depending on a network arrangement (infrastructure mode or ad hoc mode), high-accuracy synchronization is possible in any network arrangement. For example, in IEEE802.11, a synchronization error between the TSF timers is equal to or smaller than several μsec. Furthermore, even if the signal detection apparatus 100 is an apparatus complying with another wireless communication standard such as IEE802.15.1 or IEEE802.15.4, it can be used as long as it incorporates a similar timer.

The first feature information generator 105 receives a signal block from the buffer 103 at every predetermined time. The first feature information generator 105 performs signal processing for the signal block to generate first feature information 14 representing the feature of the frequency domain of the signal block. More specifically, the first feature information generator 105 may perform discrete Fourier transform (for example, Fast Fourier Transform (FFT)) for the signal block to generate the first feature information 14 indicating the signal intensity (for example, a power spectrum) in each frequency band. If a frequency band (for example, a range from 20 Hz to 20 kHz corresponding to the human audibility range) to be analyzed is divided into 32 frequency bands and the signal intensity in each frequency band is expressed by 1 byte at a log scale, the information volume of the first feature information 14 has 32 bytes. Note that a boundary frequency between adjacent frequency bands need not be decided by an arithmetical progression, and may be decided by a geometrical progression or another progression. The first feature information generator 105 outputs the first feature information 14 to the third feature information generator 106, priority allocator 108, and feature information transmitter 113.

The third feature information generator 106 receives the first feature information 14 from the first feature information generator 105. The third feature information generator 106 generates third feature information 15 representing a temporal change in the first feature information 14 across a plurality of signal blocks based on the current first feature information 14 and at least one piece of past first feature information 14 (or information indicating the feature of at least one piece of past first feature information 14). More specifically, the third feature information generator 106 may generate the third feature information 15 by processing the plural pieces of first feature information 14 as time-series data in each frequency band, and calculating, for each frequency band, the Shannon's information content (entropy) of the time-series data or the sum of absolute differences of the sample values of the time-series data between adjacent signal blocks. For example, the third feature information 15 may be 32-byte data obtained by expressing, by 1 byte, the Shannon's information content or the sum of absolute differences in each of the 32 frequency bands. The third feature information generator 106 outputs the third feature information 15 to the priority allocator 108 and feature information transmitter 113.

The server command receiver 107 receives the server command 10 from the server apparatus 200 via a network. The network may be, for example, an arbitrary wireless or wired network such as a TCP (Transmission Control Protocol)/IP (Internet Protocol) network, or 3G (3rd Generation) network. Based on the server command 10, the server command receiver 107 obtains some or all of priority characteristic information 11, a signal readout command 12, and bandwidth allocation information 13.

The priority characteristic information 11 indicates a signal characteristic (to be referred to as a priority characteristic hereinafter) for which the server apparatus 200 preferentially requests information. The signal readout command 12 includes information for specifying a past signal block to be read out from the intermediate storage 110. The bandwidth allocation information 13 indicates a bandwidth allocated to the signal detection apparatus 100 by the server apparatus 200.

The priority characteristic information 11, signal readout command 12, and bandwidth allocation information 13 may be explicitly included in the server command 10 or may be obtained when the server command receiver 107 interprets the server command 10. The server command receiver 107 outputs the priority characteristic information 11 to the priority allocator 108, provides the signal readout command 12 to the intermediate storage 110, and outputs the bandwidth allocation information 13 to the information volume limiter 112.

The priority allocator 108 receives the priority characteristic information 11 from the server command receiver 107, receives the first feature information 14 from the first feature information generator 105, and receives the third feature information 15 from the third feature information generator 106. Based on the priority characteristic information 11, first feature information 14, and third feature information 15, the priority allocator 108 allocates priority levels to a plurality of signal characteristics. The priority allocator 108 notifies the signal characteristic filter 109 of the signal characteristics allocated with the priority levels and the priority levels.

A signal characteristic to be allocated with a priority level can be decided based on the feature (for example, the frequency) of a signal transmitted by the signal source 300. The signal characteristic is typically the frequency band of the detected signal but may be different depending on information required by the server apparatus 200. The priority allocator 108 allocates the high priority level to a signal characteristic corresponding to the priority characteristic indicated by the priority characteristic information 11, as compared with the remaining signal characteristics. Note that if an expiration date is set in the priority characteristic information 11, the priority allocator 108 allocates a high priority level to the signal characteristic corresponding to the priority characteristic indicated by the priority characteristic information 11, as compared with the remaining signal characteristics, only before the expiration date. Furthermore, the priority allocator 108 may adjust the priority level of each signal characteristic based on the first feature information 14 and third feature information 15. Firstly, since it can be expected to derive significant information in a frequency band with a high signal intensity at a higher probability than in a frequency band with a low signal intensity, the priority allocator 108 may allocate a higher priority level to the frequency band as the signal intensity indicated by the first feature information 14 is higher. Secondly, since it can be expected that a significant signal exists in a frequency band including an abrupt temporal change in signal intensity at a higher probability than in a frequency band including no abrupt temporal change in signal intensity, the priority allocator 108 may allocate a higher priority level to the frequency band as a temporal change in signal intensity indicated by the third feature information 15 is more abrupt.

The signal characteristic filter 109 receives the (current) signal block from the buffer 103, and is notified of the signal characteristics and their priority levels by the priority allocator 108. The signal characteristic filter 109 performs appropriate filter processing for each notified signal characteristic to change the signal block to a format appropriate for analysis of the feature corresponding to the signal characteristic. More specifically, for each notified frequency band, the signal characteristic filter 109 may perform bandpass filter processing (for example, Butterworth filter processing) of suppressing signal components outside the frequency band. For each signal characteristic allocated with a priority level, the signal characteristic filter 109 outputs the signal block having undergone the filter processing and the priority level to the second feature information generator 111.

Furthermore, the signal characteristic filter 109 may receive a past signal block from the intermediate storage 110. In this case as well, the signal characteristic filter 109 performs filter processing for each signal characteristic, and outputs the signal block having undergone the filter processing and the priority level of the signal characteristic to the second feature information generator 111. The past signal block is read out in accordance with the signal readout command 12 based on the server command 10 from the server apparatus 200. Therefore, each signal characteristic of the past signal block may be allocated with a priority level equal to that of a signal characteristic corresponding to the priority characteristic indicated by the above-described priority characteristic information 11.

Note that the signal characteristic filter 109 may output all the signal characteristics of the signal block without any change. Also, even if the signal characteristic filter 109 is deleted, the second feature information generator 111 can generate the second feature information directly from the signal block.

The intermediate storage 110 receives a signal block from the buffer 103 and saves it at every predetermined time. Therefore, the intermediate storage 110 accumulates the signal blocks for the predetermined past time. Upon receiving the signal readout command 12 from the server command receiver 107, the intermediate storage 110 outputs specific past signal blocks to the outside (for example, the signal characteristic filter 109) in accordance with the signal readout command 12.

For each signal characteristic allocated with the priority level, the second feature information generator 111 receives the signal block having undergone the filter processing and the priority level from the signal characteristic filter 109. The second feature information generator 111 analyzes each signal block having undergone the filter processing to generate the second feature information representing the feature of the time domain of the signal block. The second feature information generator 111 may generate the second feature information including a plurality of kinds of information elements for one signal block having undergone the filter processing. The second feature information generator 111 outputs the second feature information and the priority level to the information volume limiter 112.

The second feature information may be, for example, waveform data corresponding to the signal block having undergone the filter processing. If waveform data is used as the second feature information, the second feature information generator 111 may sample the signal block having undergone the filter processing by using a sampling frequency based on the passband of the filter processing. Alternatively, the second feature information may be envelope data corresponding to the signal block having undergone the filter processing. Especially, when the frequency of a waveform represented by the signal block having undergone the filter processing is sufficiently high with respect to the time length of the signal block (for example, the expected value of the number of waves included in the signal block having undergone the filter processing is 20 or more), the second feature information generator 111 generates envelope data as the second feature information.

The second feature information may indicate a list of the appearance times of characteristic points (for example, zero-crossing points or peaks) included in the signal block having undergone the filter processing, or a list of sets (tuples) of the appearance times and signal intensities of peaks included in the signal block having undergone the filter processing. Note that the information volume of each appearance time or each tuple has a fixed length but the information volume of the entire list has a variable length since the total number of appearance times or tuples changes depending on a waveform (for example, the number of zero-crossing points or peaks) represented by the signal block having undergone the filter processing. For example, an arbitrary time included in the signal block having undergone the filter processing can be expressed by an offset amount from the beginning of the signal block. If the time length of the signal block is 100 msec and the granularity (that is, a unit time length) of the time representation is 10 μsec, the offset amount is represented by an integer falling within the range from 0 (inclusive) to 10,000 (exclusive). Consequently, the information volume at an arbitrary time included in the signal block having undergone the filter processing is at most 2 bytes. If the signal intensity is expressed by 1 byte, the information volume of each tuple described above has at most 3 bytes.

The information volume limiter 112 receives the bandwidth allocation information 13 from the server command receiver 107, and receives the second feature information and its priority level from the second feature information generator 111. The information volume limiter 112 limits the information volume of the second feature information based on the bandwidth indicated by the bandwidth allocation information 13. More specifically, if the total information volume of the pieces of second feature information received from the second feature information generator 111 exceeds the upper limit information volume corresponding to the bandwidth, the information volume limiter 112 selects some of the pieces of second feature information based on the priority levels allocated to the respective pieces of second feature information, and discards the remaining pieces of second feature information, thereby limiting the total information volume of selected second feature information 16 to the upper limit information volume or less. For example, the information volume limiter 112 may sort the pieces of second feature information in the order of priority, and select pieces of second feature information in the descending order of priority level. Alternatively, to emphasize a frequency band with a high signal intensity, the information volume limiter 112 may sort the pieces of second feature information after weighting each priority level based on the signal intensity in the corresponding frequency band. The information volume limiter 112 outputs the selected second feature information 16 to the feature information transmitter 113.

The feature information transmitter 113 receives the first feature information 14 from the first feature information generator 105, receives the third feature information 15 from the third feature information generator 106, and receives the selected second feature information 16 from the information volume limiter 112. The feature information transmitter 113 generates the feature information 20 by encoding and packetizing the first feature information 14, third feature information 15, and selected second feature information 16. The feature information transmitter 113 transmits the feature information 20 to the server apparatus 200 via the network. The network may be, for example, an arbitrary wireless or wired network such as a TCP/IP network or 3G network.

Note that to reduce the information volume of the feature information 20, the signal detection apparatus 100 compresses the first feature information 14, third feature information 15, and second feature information using a known data compression technique such as an LZ method or run length method. Since each of the first feature information 14 and the third feature information 15 corresponds to a scalar quantity in each frequency band, the information volume of each of the first feature information 14 and the third feature information 15 is smaller than that of the second feature information, and these pieces of information are continuously required by the server apparatus 200 to grasp an event (the appearance of an unknown signal source and the like) occurring in the entire space. Therefore, the first feature information 14 and third feature information 15 are preferentially transmitted over the second feature information. If reduction of the information volume by compression is insufficient, the information volume limiter 112 effectively discards some of the pieces of second feature information based on the priority levels.

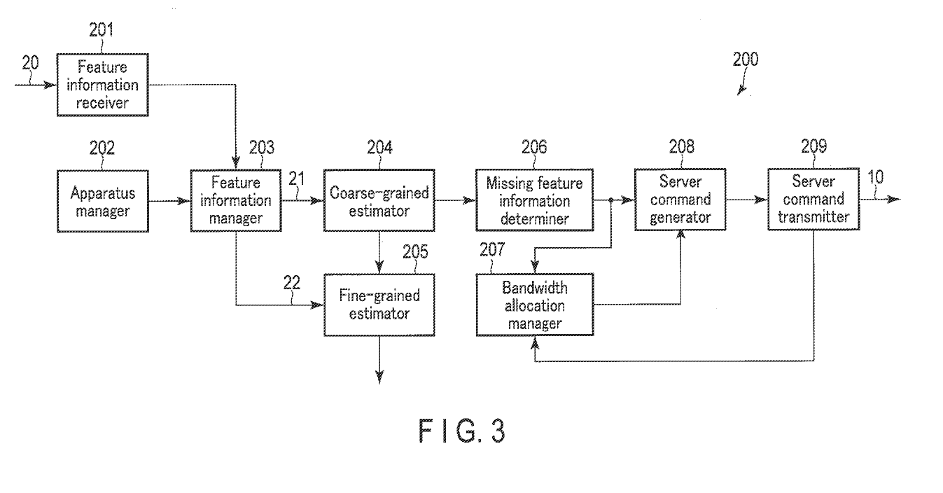

As exemplified in FIG. 3, the server apparatus 200 according to the first embodiment includes a feature information receiver 201, an apparatus manager 202, a feature information manager 203, a coarse-grained estimator 204, a fine-grained estimator 205, a missing feature information determiner 206, a bandwidth allocation manager 207, a server command generator 208, and a server command transmitter 209.

The feature information receiver 201 receives the feature information 20 from each signal detection apparatus 100 via the network. The feature information receiver 201 restores the first feature information, second feature information, and third feature information by depacketizing and decoding the feature information 20. Note that the first feature information and third feature information represent the features of the frequency domain of the current (latest) signal block, and the second feature information represents the feature of the time domain of the current or past signal block. The feature information receiver 201 outputs the first feature information, second feature information, and third feature information to the feature information manager 203.

The apparatus manager 202 manages the location information of each signal detection apparatus 100. The location information of each signal detection apparatus 100 is known to the apparatus manager 202 when the location of the signal source 300 is estimated. The location information of each signal detection apparatus 100 may be manually or automatically set at the time of design and installation of the signal detection apparatus 100, or autonomously estimated by the signal detection apparatus 100, the server apparatus 200, or another apparatus. For example, microphones or loudspeakers are attached to the respective signal detection apparatuses 100, and any one of the loudspeakers transmits an acoustic wave, thereby making it possible to estimate the location information (which may be azimuth information) of each signal detection apparatus 100 based on a difference in propagation time of the acoustic wave between the signal detection apparatuses 100. Each signal detection apparatus 100 may periodically estimate the location information, and transmit it to the server apparatus. The feature information manager 203 reads out the location information of each signal detection apparatus 100 managed by the apparatus manager 202, as needed.

The feature information manager 203 receives the first feature information, second feature information, and third feature information from the feature information receiver 201, and reads out the location information of each signal detection apparatus 100 from the feature information manager 203, as needed. The feature information manager 203 manages the first feature information, second feature information, and third feature information. More specifically, the feature information manager 203 maps (associates) the first feature information, second feature information, and third feature information to (with) the location information of the signal detection apparatus 100 corresponding to the transmission source of the first feature information, second feature information, and third feature information. The feature information manager 203 outputs mapped first and third feature information 21 to the coarse-grained estimator 204, and outputs mapped second feature information 22 to the fine-grained estimator 205.

The coarse-grained estimator 204 receives the mapped first and third feature information 21 from the feature information manager 203. Based on the mapped first and third feature information 21, the coarse-grained estimator 204 estimates the signal source 300 at a coarser granularity than that of the fine-grained estimator 205. The coarse-grained estimator 204 notifies the fine-grained estimator 205 and missing feature information determiner 206 of the coarse-grained estimation result of the signal source 300.

More specifically, the coarse-grained estimator 204 estimates in which of a plurality of regions determined based on the location information of each signal detection apparatus 100 the signal source 300 is located, and estimates the characteristic (typically, the frequency band) of a signal transmitted by the signal source 300. For example, if a specific signal detection apparatus 100 detects a signal of the highest intensity in a specific frequency band, the coarse-grained estimator 204 may estimate that the signal source 300 is located in one of one or more regions determined based on the location information of the specific signal detection apparatus 100, and estimate the specific frequency band as the characteristic of the signal.

The coarse-grained estimation result of the signal source 300 may be a list including five information elements of, for example, a signal source ID, estimated region information, signal characteristic information, last detection time, and certainty factor. The signal source ID is information for identifying the signal source 300 estimated by the coarse-grained estimator 204. The estimated region information indicates one or more regions in which the signal source 300 is estimated to be located.

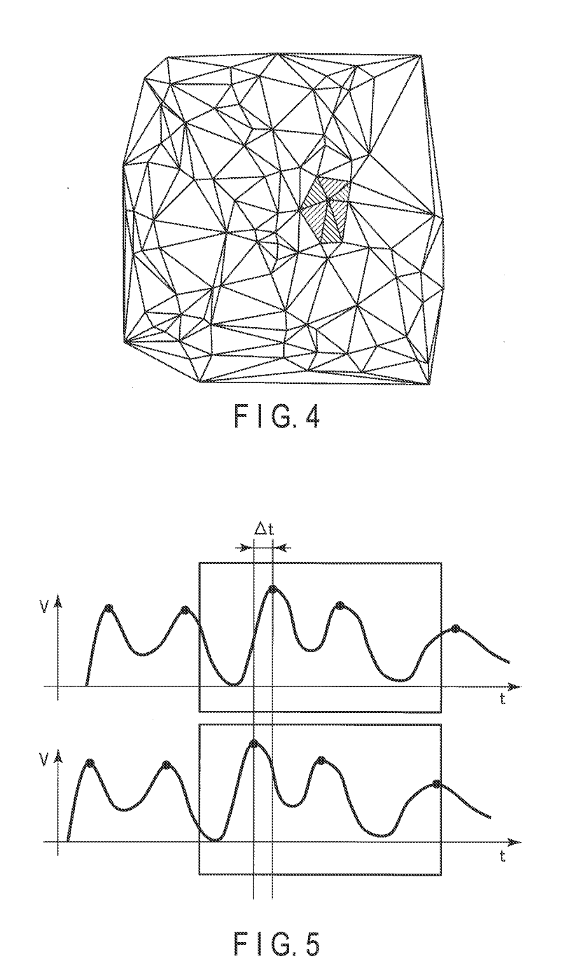

For example, as shown in FIG. 4, the region may be defined by a Delaunay triangle obtained by drawing a two- or three-dimensional Delaunay diagram by setting the location of the signal detection apparatus 100 as a vertex. For example, if a specific signal detection apparatus 100 detects a signal of the highest intensity in a specific frequency band, the coarse-grained estimator 204 may estimate that the signal source 300 which has transmitted the signal is located in any one of one or more Delaunay triangles having the location of the specific signal detection apparatus 100 as a vertex. In this case, the estimated region information can be represented by using, for example, the identifier of the specific signal detection apparatus 100.

Alternatively, the region may be defined by a space where the distance from each signal detection apparatus 100 is equal to or smaller than a threshold. For example, if a specific signal detection apparatus 100 detects a signal of the highest intensity in a specific frequency band, the coarse-grained estimator 204 may estimate that a space where the distance from the specific signal detection apparatus 100 is equal to or smaller than the threshold is a region where the signal source 300 which has transmitted the signal is located. In this case, the estimated region information can be represented by using, for example, the identifier of the specific signal detection apparatus 100.

The signal characteristic information indicates one or more characteristics of a signal estimated to have been transmitted from the signal source 300. The last detection time indicates the time at which the signal estimated to have been transmitted from the signal source 300 is last detected. The certainty factor indicates the reliability of the coarse-grained estimation result of the signal source 300. The signal source 300 is classified as a known signal source or unknown signal source depending on the certainty factor.

If a signal having a significant signal intensity is detected a plurality of times within a given time in a region where the signal source 300 classified as a known signal source is estimated not to be located, the coarse-grained estimator 204 may classify the signal source 300 of the signal as a known signal source. Note that the certainty factor decreases with time after the last detection time. The coarse-grained estimator 204 downgrades the signal source 300 to an unknown signal source when the certainty factor of the signal source 300 classified as a known signal source becomes lower than a threshold.

The fine-grained estimator 205 receives the mapped second feature information 22 from the feature information manager 203, and is notified of the coarse-grained estimation result by the coarse-grained estimator 204. Based on the mapped second feature information 22 and the coarse-grained estimation result, the fine-grained estimator 205 estimates the location of the signal source 300 classified as a known signal source by the coarse-grained estimator 204 with a finer granularity than that of the coarse-grained estimator 204. The fine-grained estimator 205 may output the fine-grained estimation result outside the server apparatus 200.

For example, the fine-grained estimator 205 may estimate the location of the signal source 300 by solving simultaneous equations associated with a difference in propagation time of the signal from the signal source 300 between the plurality of signal detection apparatuses 100. For example, let dt [sec] be the time difference between the time at which a common signal reaches a given signal detection apparatus 100 and the time at which the common signal reaches another signal detection apparatus 100, and s [m/sec] be the propagation speed of the signal. Then, the difference in distances from the signal source 300 between the two signal detection apparatuses 100 can be estimated as dt·s [m]. Since the synchronization clocks 104 of the plurality of signal detection apparatuses 100 are in synchronism with each other with high accuracy, the fine-grained estimator 205 can refer to a correct propagation time difference.

The fine-grained estimator 205 may derive an estimated location having a high likelihood by solving the above simultaneous equations using a numerical calculation algorithm such as Newton's method. Since the fine-grained estimator 205 can obtain a solution with an error by using Newton's method, the solution may be adopted as long as the error is equal to or smaller than a threshold. The fine-grained estimator 205 may consider the second feature information based on the past signal block in addition to the second feature information based on the latest signal block.

For each signal source 300 classified as a known signal source by the coarse-grained estimator 204, the missing feature information determiner 206 determines whether the second feature information corresponding to each piece of signal characteristic information has been sufficiently collected from the plurality of signal detection apparatuses 100 corresponding to each piece of estimated region information. The signal detection apparatuses 100 corresponding to the estimated region information may include, for example, a specific signal detection apparatus 100 which has detected the highest signal intensity in a frequency band of interest, and a plurality of other signal detection apparatuses 100 whose hop count from the specific signal detection apparatus 100 is equal to or smaller than a threshold. Alternatively, the signal detection apparatuses 100 corresponding to the estimated region information may include, for example, a specific signal detection apparatus 100 which has detected the highest signal intensity in a frequency band of interest, and a plurality of other signal detection apparatuses 100 whose distance from the specific signal detection apparatus 100 is equal to or smaller than a threshold. If there is missing feature information indicating the second feature information which needs to be collected, the missing feature information determiner 206 outputs the missing feature information to the bandwidth allocation manager 207 and server command generator 208. The missing feature information includes signal characteristic information for which the second feature information has not been sufficiently collected, and information for identifying the signal detection apparatus 100 from which the second feature information corresponding to the signal characteristic information needs to be collected.

The bandwidth allocation manager 207 receives the missing feature information from the missing feature information determiner 206, and is notified of a bandwidth usable to transmit the feature information 20 by the server command transmitter 209. The bandwidth allocation manager 207 controls bandwidth allocation to the respective signal detection apparatuses 100 based on the missing feature information and the bandwidth usable to transmit the feature information 20. The bandwidth allocation manager 207 outputs, to the server command generator 208, bandwidth allocation information indicating a bandwidth allocated to each signal detection apparatus 100.

More specifically, the bandwidth allocation manager 207 dynamically adjusts a bandwidth to be allocated to each signal detection apparatus 100 in accordance with the information volume of the second feature information which needs to be collected from the signal detection apparatus 100, to the extent that the total sum of bandwidths to be allocated to the plurality of signal detection apparatuses 100 does not exceed the bandwidth usable to transmit the feature information 20. That is, the bandwidth allocation manager 207 allocates a wider bandwidth to the signal detection apparatus 100 from which the second feature information of a larger size needs to be collected.

The server command generator 208 receives the missing feature information from the missing feature information determiner 206, and receives the bandwidth allocation information from the bandwidth allocation manager 207. The server command generator 208 generates a server command based on the missing feature information and the bandwidth allocation information. The server command generator 208 outputs the server command to the server command transmitter 209.

For example, based on the missing feature information, the server command generator 208 may generate a server command to cause a specific signal detection apparatus 100 to transmit the second feature information corresponding to a specific signal band based on a past or future detected signal. Furthermore, based on the bandwidth allocation information, the server command generator 208 may generate a server command to notify each signal detection apparatus 100 of a bandwidth to be allocated to it. Note that the server command generator 208 may set an expiration date for the server command. Even if the expiration date is set for the server command, the server command generator 208 can validate the server command for an arbitrary period by repeatedly generating the next server command before the expiration date.

The server command transmitter 209 receives the server command from the server command generator 208, and transmits the server command 10 to each signal detection apparatus 100 via the network. Furthermore, the server command transmitter 209 may predict a bandwidth usable to transmit the feature information 20, and notify the bandwidth allocation manager 207 of it.

### First Application Example

The location estimation system according to the first embodiment can be used to estimate, for example, the location of an unknown sound source in a room. More specifically, if a human or another mobile unit performs some activity in a room, the server apparatus 200 analyzes a sound generated by the activity to estimate a location (sound source location) where the activity has been performed.

If there are a plurality of sound sources, sounds generated by the respective sound sources can be preferably discriminated based on signal characteristics. For example, the respective sound sources may generate sounds having different spectra. Preferably, a given sound source continuously generates a sound and another sound source intermittently generates a sound.

Since the temperature distribution of a general room is almost uniform, the speed of sound can be considered to be constant in the above-described fine-grained estimation processing. In a special room where the temperature distribution is significantly nonuniform, the propagation time difference may be corrected in consideration of a change in speed of sound caused by the temperature distribution. To measure the temperature distribution, a thermometer may be attached to each signal detection apparatus 100 or another arbitrary technique may be used.

The sensor 101 typically includes a nondirectional microphone, and can uniformly detect sounds (acoustic signals) coming from every direction. Alternatively, the sensor 101 may include a directional microphone having a known directional characteristic, or a stereo microphone or microphone array in which the location relationship between microphones is known. If the direction of a sound source is known (based on, for example, information fed back from the server apparatus 200), it is possible to detect a sound coming from the direction with high sensitivity by using the directional microphone, stereo microphone, or microphone array as the sensor 101. It is possible to largely suppress a noise component by performing such sound source separation (more generally, signal source separation), thereby improving the quality of the first feature information, second feature information, and third feature information.

In addition, a transmitter such as a loudspeaker may be arranged at one or more known locations. This transmitter may be attached to one of the signal detection apparatuses 100 or arranged independently of each signal detection apparatus 100. If the transmitter is arranged independently of each signal detection apparatus 100, it preferably includes a clock synchronized with the synchronization clock 104 incorporated in each signal detection apparatus 100. This transmitter transmits a specific sound at a predetermined time, and the sensor 101 of each signal detection apparatus 100 detects the specific sound. The specific sound is preferably transmitted at the time at which a silent environment is obtained at high probability. The time indicates, for example, a time such as early morning or late at night other than office or business hours when a space as a location estimation target is an office or store, or the maintenance time when the space is a factory. The apparatus manager 202 analyzes the propagation time of the specific sound to each signal detection apparatus 100, thereby setting or correcting the location information of the signal detection apparatus 100. The specific sound may be a pulse sound or a sound obtained by converting an arbitrary code (for example, an M-sequence code).

Note that at the time of transmitting the above specific sound, each signal detection apparatus 100 may further detect a signal corresponding to a reflected sound in addition to a direct sound. The server apparatus 200 accumulates the second feature information based on the reflected sound as ambient environment information. Based on the accumulated pieces of ambient environment information, the server apparatus 200 can create a model for estimating the reflected sounds (in fact, the pieces of second feature information generated based on the reflected sounds) of a sound transmitted by a sound source arranged at an arbitrary location.

The model for estimating the reflected sounds may be a sequence of the arrival time and signal intensity (t₁, v₁) of the direct sound at one or a plurality of observable locations (x′, y′, z′) and the peak times and signal intensities (t2, v2), (t3, v3), . . . of the reflected sounds, which are associated with the generation location (x, y, z), generation time (t₀), and signal intensity (v₀) of the specific sound. When it is assumed that a sound of an arbitrary signal intensity (v₀) is generated at an arbitrary location (x, y, z) at an arbitrary time (t₀), the model may have a function of estimating a sequence of the arrival time and signal intensity (t₁, v₁) of the direct sound at an arbitrary location (x′, y′, z′) except for the above location and the peak times and signal intensities (t2, v2), (t3, v3), . . . of the reflected sounds. The model may correspond to a three-dimensional model in a space as a location estimation target, which is generated based on the reflected sounds (signals themselves or the pieces of second feature information generated based on the signals) detected by the plurality of signal detection apparatuses 100.

Each signal detection apparatus 100 may generate the second feature information after performing signal processing of reducing reflected sound components from the signal block based on the model. Alternatively, before calculating the correlation between two pieces of second feature information (to be described later), the fine-grained estimator 205 may reduce components based on reflected sounds of the two pieces of feature information. Note that the reduction processing need not be applied to all the peak signals of the reflected sounds, and may only be applied to the peak signal (that is, the peak signal having a large influence) of a reflected sound having a peak time and signal intensity which differ from the arrival time and signal intensity of the direct sound within certain thresholds, respectively.

The synchronization clock 104 generates, as time information, a pulse signal having a cycle set in advance. The cycle of the pulse signal is used as the time length (time frame) of the signal block.

The first feature information generator 105 generates the first feature information 14 indicating a power spectrum by performing discrete Fourier transform for the signal block. The third feature information generator 106 generates the third feature information 15 by processing x (≧2) pieces of first feature information 14 as time-series data of each frequency band, and calculating, for each frequency band, the sum of absolute differences (SAD) of the sample values of the time-series data between adjacent signal blocks by:

$$SAD = {\sum }_{j = 2}^{x} \vert {p}_{j} - {p}_{j - 1} \vert \qquad ( 1 )$$

where pⱼ represents the jth sample value of the time-series data. As described above, the third feature information generator 106 may calculate a Shannon's information content instead of the sum of absolute differences.

The priority allocator 108 allocates the highest priority level to a frequency band corresponding to the priority characteristic indicated by the priority characteristic information 11. Furthermore, the priority allocator 108 allocates priority levels to frequency bands which do not correspond to the priority characteristic based on the first feature information 14 and third feature information 15. More specifically, the priority allocator 108 allocates a low priority level to a frequency band having a low signal intensity since significant information can be derived with a low probability. The priority levels of frequency bands having almost equal signal intensities are determined based on the amount of an abrupt temporal change in the signal intensity. Therefore, let P₁ be a priority level allocated to a frequency band having a high signal intensity and including an abrupt temporal change in signal intensity, P₂ be a priority level allocated to a frequency band having a high signal intensity and including a gradual temporal change in signal intensity, P₃ be a priority level allocated to a frequency band having a low signal intensity and including an abrupt temporal change in signal intensity, and P₄ be a priority level allocated to a frequency band having a low signal intensity and including a gradual temporal change in signal intensity. Then, P₁>P₂>P₃>P₄ is generally satisfied. For example, the priority allocator 108 may calculate the priority level P by:

P=α·C₁+β·C₂ (2)

where C₁ represents a value obtained by normalizing the signal intensity in the target frequency band indicated by the first feature information 14 within, for example, the range from 0 to 1, C₂ represents a value obtained by normalizing the temporal change in signal intensity in the target frequency band indicated by the third feature information 15 within, for example, the range from 0 to 1, and α and β are weighting factors. For example, α=10 and β=1 are determined so as to satisfy a relationship of α>>β. If the relationship of α>>β is satisfied, the priority level P largely increases or decreases depending on the signal intensity, and slightly increases or decreases depending on the temporal change in signal intensity. As a result, for example, a reverse phenomenon like P₂<P₃ hardly occurs.

The second feature information generator 111 generates, as the second feature information, a list of tuples of the appearance times and signal intensities of peaks included in the signal block having undergone the filter processing for each frequency band. More specifically, the second feature information generator 111 detects a peak based on a waveform in a low-frequency band, and detects a peak based on an envelope in a high-frequency band.

A reference frequency for determining whether an arbitrary frequency band is a low-frequency band or high-frequency band depends on the synchronization accuracy of the synchronization clocks 104 but may be determined to be a value corresponding to 1/10 of the time length of the time frame. That is, if the time length of the time frame is 10 msec (100 Hz), the reference frequency may be 1 kHz (a cycle of 1 msec). If a sound of a frequency higher than the reference frequency continues from the start of the time frame to its end, the expected value of the number of waves included in the time frame is 20 or more. Note that the reference frequency is not limited to the value corresponding to 1/10 of the time length of the time frame, and may be set to an arbitrary value.

Assume that W₀ represents the upper limit information volume corresponding to the bandwidth indicated by the bandwidth allocation information 13. In this case, the information volume limiter 112 calculates an upper limit information volume W allocatable to the second feature information by subtracting an information volume necessary to transmit the first feature information 14 and third feature information 15 from the upper limit information volume W₀. The information volume limiter 112 can select the pieces of second feature information in descending order of priority level as long as the information volume necessary to transmit the selected second feature information 16 is equal to or smaller than the upper limit information volume W.

The server apparatus 200 manages a set S of estimated sound sources. Each element of the set S includes a list of the start time of a frame in which a signal estimated to have been transmitted from the sound source is detected, the estimated location of the sound source, and frequency bands in which the signal is detected. Note that the server apparatus 200 may initialize the set S to a null set at the time of, for example, installation or reactivation of the location estimation system or the server apparatus 200.

The coarse-grained estimator 204 searches for the smallest value in each frequency band from the signal intensities in the frequency band indicated by the pieces of first feature information collected from the respective signal detection apparatuses 100. For each frequency band, the coarse-grained estimator 204 obtains the background ratio by setting the found smallest value as a background and dividing each signal intensity in the frequency band by the background. The coarse-grained estimator 204 performs coarse-grained estimation of the location of the signal source 300 of a signal corresponding to each background ratio in descending order of background ratio, and determines whether the signal source 300 coincides with any one of known signal sources. If the coarse-grained estimator 204 determines that the signal source 300 does not coincide with any of the known signal sources, it considers the signal source 300 as an unknown signal source. Note that the number of background ratios which can be included as determination targets depends on the available calculation resource of the coarse-grained estimator 204.

The fine-grained estimator 205 may calculate the correlation between the pieces of second feature information collected from the two signal detection apparatuses 100, and derive the difference in propagation time of a signal from the signal source 300 between the two signal detection apparatuses 100 based on the correlation. More specifically, as exemplified in FIG. 5, the fine-grained estimator 205 calculates the correlation between the two pieces of second feature information when one of the two pieces of second feature information is offset by Δt where Δt represents an offset amount. The fine-grained estimator 205 calculates the correlation a plurality of times by changing Δt. The fine-grained estimator 205 then finds Δt which maximizes the correlation, and uses Δt as the propagation time difference. Note that the fine-grained estimator 205 may set Δt, which maximizes the correlation, as the first candidate value of the propagation time difference, and use the remaining offset amounts Δt as the second candidate value and subsequent candidate values of the propagation time difference in descending order of correlation.

When, for example, the appearance times of respective peaks indicated by one of the pair of pieces of second feature information are offset by Δt, the correlation of the pair may be indicated by the number of offset appearance times which respectively match the appearance times of peaks indicated by the other one of the pair. Alternatively, the correlation may be indicated by a ratio obtained by dividing the number of matching appearance times by the total number of peaks included in the pair. Note that a match between two appearance times indicates that the time difference between the appearance times is smaller than a predetermined threshold.

Note that it is inefficient to calculate the correlation based on a round-robin system since the calculation amount is large. For this reason, the fine-grained estimator 205 may calculate the correlation by preferentially combining pieces of second feature information collected from signal detection apparatuses 100 each of which has detected a high intensity with respect to a signal estimated to have been transmitted from the common signal source 300. Note that the number of pairs of pieces of second feature information which can be included as correlation calculation targets depends on the available calculation resource of the fine-grained estimator 205.

The fine-grained estimator 205 may reduce the calculation amount necessary for location estimation of the signal source 300 by assuming the location of the signal source 300 using, for example, a particle filter method. More specifically, the fine-grained estimator 205 represents the location candidate of the signal source 300 by a particle, and calculates the likelihood when assuming that the signal source 300 is located at each of a plurality of particles. When estimating the location of the signal source 300 for the first time, the fine-grained estimator 205 calculates the likelihood by randomly arranging a plurality of particles in an estimated region (especially, near the signal detection apparatus 100 which has detected the highest intensity with respect to a signal estimated to have been transmitted from the signal source 300). The fine-grained estimator 205 then maintains particles having high likelihoods and deletes particles having low likelihoods. Furthermore, the fine-grained estimator 205 may randomly move or newly generate a particle, and then calculate the likelihood.

If the estimated location of the signal source 300 evidently falls outside a space (for example, a room) as a location estimation target, the fine-grained estimator 205 may discard the estimated location as an error caused by the influence of a reflected signal or the like.

### Second Application Example

When, for example, there are one or more users wearing headsets (especially, headset microphones) and one or more machines for generating known sounds in a room, the location estimation system according to the first embodiment can record the action (for example, utterance, an operation on the machine, or the like) of the user and the estimated location of the user at this time in association with each other.

The machine need not be fixed and may be movable. More specifically, if the user utters a sound or an event of causing the machine to generate a known sound occurs in the room, the server apparatus 200 analyzes the sound to estimate the location of the user at this time. The location estimation system can, for example, estimate the user location when the user utters, and estimate, when the user performs a specific operation on the machine and a known beep is generated for feedback of information indicating that the operation has been performed, the user location at the time of the operation of the user.

The headset preferably includes a clock synchronized with the synchronization clock 104 incorporated in each signal detection apparatus 100, acquires time information at which voice is detected, and transmits the time information to the server apparatus 200. Since the time lag from when the user utters until the headset detects the voice can be estimated to be constant and very short, the server apparatus 200 processes the time information collected from the headset as the utterance time of the user. The server apparatus 200 may calculate the propagation time of a sound to each signal detection apparatus 100 by subtracting the utterance time from the start time of a frame in which the signal detection apparatus 100 detects the signal of the voice uttered by the user. The server apparatus 200 can estimate the user location at the time of the utterance of the user by calculating the distances from the phonic organ of the user to three signal detection apparatuses 100 based on the propagation times and speed of sound, and solving simultaneous linear equations with three-dimensional coordinate components of the phonic organ as three unknowns.

Similarly, the above machine preferably includes a clock synchronized with the synchronization clock 104 incorporated in each signal detection apparatus 100, acquires time information at which a beep is generated, and transmits the time information to the server apparatus 200. Since the time lag from when the user performs an operation until the machine generates a beep can be estimated to be constant and very short, the server apparatus 200 processes the time information collected from the machine as the operation time of the user. The server apparatus 200 may calculate the propagation time of the beep to each signal detection apparatus 100 by subtracting the operation time from the start time of a frame in which the signal detection apparatus 100 detects the signal of the beep generated by the machine. The server apparatus 200 can estimate the user location at the time of the user operation on the machine by calculating the distances from the machine to three signal detection apparatuses 100 based on the propagation times and speed of sound, and solving simultaneous linear equations with three-dimensional coordinate components of the machine as three unknowns.

Note that in the second application example, the signal generated by the sound source is known (for example, a voice received by the headset or a predetermined beep generated by the machine). Therefore, the coarse-grained estimator 204 can correctly estimate signal characteristic information by analyzing the signal. Furthermore, the fine-grained estimator 205 can calculate the propagation time difference more correctly by calculating the correlation using the pieces of second feature information generated based on the signal.

### Third Application Example

The location estimation system according to the first embodiment can be utilized for, for example, surveillance of a store by estimating the location of the sound source of a vibration sound (for example, the footsteps of people walking on the floor, a sound generated when a person places on or takes out an object from a rack) transmitted through the floor or rack (for example, a product storage rack).

The sensor 101 is a contact microphone attached to the floor, rack, wall, or the like. Note that the speed of sound can be assumed to be constant in the material of the floor, rack, or wall. The fine-grained estimator 205 can accumulate pieces of information for estimating a route along which a shopper moves around in a shop, when the shopper picks up a specific product placed on a product display rack (in addition, when the shopper returns the product to the product display rack), and the like by continuously estimating the sound source using the above-described technique.

As described above, the location estimation system according to the first embodiment includes a plurality of signal detection apparatuses distributed and arranged in a space, and a server apparatus for controlling the plurality of signal detection apparatuses. Each of the plurality of signal detection apparatuses detects a signal, and generates the first feature information representing the feature of the frequency domain of the signal and the second feature information representing the feature of the time domain of the signal. The server apparatus collects pieces of first feature information and pieces of second feature information from the plurality of signal detection apparatuses, performs coarse-grained estimation of the location of a signal source based on the pieces of first feature information, and also performs fine-grained estimation of the location of the signal source based on the coarse-grained estimation result and the pieces of second feature information. The server apparatus determines the second feature information which needs to be collected for fine-grained estimation, and commands the signal detection apparatus, estimated to exist around the signal source, to transmit the second feature information while dynamically controlling bandwidth allocation to the respective signal detection apparatuses. Each signal detection apparatus generates the second feature information for a plurality of signal characteristics, and allocates a priority level to each signal characteristic based on a server command or the like. The signal detection apparatus adapts the information volume of the second feature information to be transmitted to the server to the bandwidth allocated by the server apparatus by selecting and discarding the second feature information based on the priority level. Therefore, this location estimation system can efficiently (that is, without wasting the bandwidth) collect the second feature information necessary for fine-grained estimation, and estimate the location of the signal source with high accuracy.

At least a part of the processing in the above-described embodiments can be implemented using a general-purpose computer as basic hardware. A program implementing the processing in each of the above-described embodiments may be stored in a computer readable storage medium for provision. The program is stored in the storage medium as a file in an installable or executable format. The storage medium is a magnetic disk, an optical disc (CD-ROM, CD-R, DVD, or the like), a magnetooptic disc (MO or the like), a semiconductor memory, or the like. That is, the storage medium may be in any format provided that a program can be stored in the storage medium and that a computer can read the program from the storage medium. Furthermore, the program implementing the processing in each of the above-described embodiments may be stored on a computer (server) connected to a network such as the Internet so as to be downloaded into a computer (client) via the network.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A signal detection apparatus comprising:
a sensor that detects a signal;
a clock that is synchronized with another clock incorporated in another signal detection apparatus;
a first generator that generates first feature information representing a feature of a frequency domain of a signal block obtained by performing block formation of the signals from the sensor at every predetermined time based on time information of the clock;
an allocator that allocates priority levels to a plurality of signal characteristics of the signal block;
a second generator that generates second feature information representing a feature of a time domain of the signal block for each of the plurality of signal characteristics;
a receiver that receives a server command indicating a bandwidth allocated by a server apparatus from the server apparatus;
a limiter that, if a total information volume of the pieces of second feature information exceeds an upper limit information volume corresponding to the bandwidth, selects some of the pieces of second feature information and discards remaining pieces of second feature information based on the priority levels allocated to the pieces of second feature information to limit an information volume of the selected pieces of second feature information not to exceed the upper limit information volume; and
a transmitter that transmits the first feature information and the selected pieces of second feature information to the server apparatus.

2. The signal detection apparatus according to claim 1, wherein
the server command further indicates a priority characteristic corresponding to a signal characteristic for which the server apparatus preferentially requests information, and
the allocator allocates a high priority level to the signal characteristic corresponding to the priority characteristic, as compared with other signal characteristics.

3. The signal detection apparatus according to claim 1, wherein the allocator adjusts the priority levels to be allocated to the plurality of signal characteristics based on the first feature information.

4. The signal detection apparatus according to claim 1, wherein the first feature information indicates a signal intensity in each frequency band of the signal block.

5. The signal detection apparatus according to claim 4, wherein
the plurality of signal characteristics correspond to a plurality of frequency bands, and
the limiter sorts the pieces of second feature information after weighting each priority level based on a signal intensity for a corresponding signal characteristic, and selects the pieces of second feature information in descending order of weighted priority level.

6. The signal detection apparatus according to claim 1, further comprising a third generator that generates third feature information by processing the first feature information across a plurality of signal blocks as time-series data in each frequency band, and calculating, for each frequency band, one of a Shannon's information content of the time-series data and a sum of absolute differences of sample values of the time-series data between adjacent signal blocks,
wherein the transmitter further transmits the third feature information to the server apparatus.

7. The signal detection apparatus according to claim 6, wherein the allocator adjusts the priority levels to be allocated to the plurality of signal characteristics based on the third feature information.

8. The signal detection apparatus according to claim 1, wherein the second feature information includes a list of tuples of appearance times of peaks included in the signal block and signal intensities of the peaks.

9. The signal detection apparatus according to claim 1, further comprising an estimator that estimates one of location information and azimuth information of at least one of the signal detection apparatus and the other signal detection apparatus based on a difference in propagation time of a signal,
wherein the transmitter further transmits the estimated one of the location information and the azimuth information to the server apparatus.

10. The signal detection apparatus according to claim 1, wherein the sensor includes at least one of a nondirectional microphone, a directional microphone having a known directional characteristic, one of a stereo microphone and a microphone array in which a location relationship between microphones is known, and a contact microphone.

11. The signal detection apparatus according to claim 1, wherein the sensor performs signal source separation based on an arriving direction of the signal.

12. The signal detection apparatus according to claim 1, further comprising an intermediate storage that accumulates signal blocks for a predetermined past time, and outputs, if the server command corresponds to a signal readout command for a specific past signal block, the specific past signal block to the outside,
wherein the second generator generates second feature information representing a feature of a time domain of the specific past signal block for each of the plurality of signal characteristics.

13. A server apparatus comprising:
a receiver that receives, from each of a plurality of signal detection apparatuses, first feature information representing a feature of a frequency domain of a signal detected by the signal detection apparatus, and second feature information representing a feature of a time domain of the signal;
an apparatus manager that manages pieces of location information of the plurality of signal detection apparatuses;
a feature information manager that maps the first feature information and the second feature information to the location information of the corresponding signal detection apparatus;
a first estimator that obtains a coarse-grained estimation result by estimating, based on the mapped first feature information, in which of a plurality of regions determined based on the location information of the signal detection apparatus each of at least one signal source is located, and a characteristic of a signal transmitted by the signal source;
a second estimator that estimates, based on the coarse-grained estimation result and the mapped second feature information, a location of each of the at least one signal source with a finer granularity than that of the first estimator;
a determiner that specifies missing feature information indicating second feature information which needs to be collected, by determining for each of the at least one signal source whether second feature information corresponding to the characteristic of the signal transmitted by the signal source has been sufficiently collected;
a bandwidth allocation manager that controls bandwidth allocation to the plurality of signal detection apparatuses based on the missing feature information and a bandwidth usable by the plurality of signal detection apparatuses to transmit the first feature information and the second feature information, and obtains bandwidth allocation information indicating a bandwidth allocated to each of the plurality of signal detection apparatuses;
a generator that generates a server command for each of the plurality of signal detection apparatuses based on the missing feature information and the bandwidth allocation information; and
a transmitter that transmits the server command to the plurality of signal detection apparatuses.

14. The server apparatus according to claim 13, wherein if a specific signal detection apparatus detects a signal of a highest intensity in a specific frequency band, the first estimator estimates that a signal source of the signal is located in one of at least one region determined based on location information of the specific signal detection apparatus.

15. The server apparatus according to claim 13, wherein if a specific signal detection apparatus detects a signal of a highest intensity in a specific frequency band, the first estimator estimates that a signal source which has transmitted the signal is located in one of at least one Delaunay triangle having a location of the specific signal detection apparatus as a vertex.

16. The server apparatus according to claim 13, wherein if a specific signal detection apparatus detects a signal of a highest intensity in a specific frequency band, the first estimator estimates that a space where a distance from the specific signal detection apparatus is not larger than a threshold is a region where a signal source which has transmitted the signal is located.

17. The server apparatus according to claim 13, wherein the second estimator estimates, for each of the at least one signal source, a location of the signal source by solving simultaneous equations associated with a difference in propagation time of a signal from the signal source between the plurality of signal detection apparatuses.

18. The server apparatus according to claim 17, wherein
the second feature information includes a list of appearance times of peaks included in a signal block obtained by performing block formation of signals detected by each of the plurality of signal detection apparatuses at every predetermined time,
the second estimator calculates a correlation when one of a pair of pieces of second feature information collected from two of the plurality of signal detection apparatuses is temporally offset, and uses an offset amount which maximizes the correlation as a propagation time difference between the two signal detection apparatuses, and
when appearance times of respective peaks indicated by one of the pair of pieces of second feature information are temporally offset, the correlation is indicated by one of the number of offset appearance times which respectively match appearance times of peaks indicated by the other one of the pair and a ratio obtained by dividing the number of matching appearance times by the total number of peaks included in the pair.

19. The server apparatus according to claim 17, wherein the second estimator calculates a correlation when one of a pair of pieces of second feature information collected from two of the plurality of signal detection apparatuses is temporally offset, calculates an offset amount which maximizes the correlation as a first candidate value of a propagation time difference between the two signal detection apparatuses, and calculates an offset amount which secondly maximizes the correlation as a second candidate value of the propagation time difference.

20. A location estimation system comprising a server apparatus and a plurality of signal detection apparatuses,
the server apparatus comprises:
a receiver that receives, from each of the plurality of signal detection apparatuses, first feature information representing a feature of a frequency domain of a signal detected by the signal detection apparatus, and second feature information representing a feature of a time domain of the signal;
an apparatus manager that manages pieces of location information of the plurality of signal detection apparatuses;
a feature information manager that maps the first feature information and the second feature information to the location information of the corresponding signal detection apparatus;
a first estimator that obtains a coarse-grained estimation result by estimating, based on the mapped first feature information, in which of a plurality of regions determined based on the location information of the signal detection apparatus each of at least one signal source is located, and a characteristic of a signal transmitted by the signal source;
a second estimator that estimates, based on the coarse-grained estimation result and the mapped second feature information, a location of each of the at least one signal source with a finer granularity than that of the first estimator;
a determiner that specifies missing feature information indicating second feature information which needs to be collected, by determining for each of the at least one signal source whether second feature information corresponding to the characteristic of the signal transmitted by the signal source has been sufficiently collected;
a bandwidth allocation manager that controls bandwidth allocation to the plurality of signal detection apparatuses based on the missing feature information and a bandwidth usable by the plurality of signal detection apparatuses to transmit the first feature information and the second feature information, and obtains bandwidth allocation information indicating a bandwidth allocated to each of the plurality of signal detection apparatuses;
a generator that generates a server command for each of the plurality of signal detection apparatuses based on the missing feature information and the bandwidth allocation information; and
a transmitter that transmits the server command to the plurality of signal detection apparatuses, and
each of the plurality of signal detection apparatuses comprises:
a sensor that detects a signal;
a clock that is synchronized with another clock incorporated in another signal detection apparatus;
a first generator that generates first feature information representing a feature of a frequency domain of a signal block obtained by performing block formation of the signals from the sensor at every predetermined time based on time information of the clock;
an allocator that allocates priority levels to a plurality of signal characteristics of the signal block;
a second generator that generates second feature information representing a feature of a time domain of the signal block for each of the plurality of signal characteristics;
a receiver that receives a server command indicating a bandwidth allocated by the server apparatus from the server apparatus;
a limiter that, if a total information volume of the pieces of second feature information exceeds an upper limit information volume corresponding to the bandwidth, selects some of the pieces of second feature information and discards remaining pieces of second feature information based on the priority levels allocated to the pieces of second feature information to limit an information volume of the selected pieces of second feature information not to exceed the upper limit information volume; and
a transmitter that transmits the first feature information and the selected pieces of second feature information to the server apparatus.
